(19) United States
(12) Patent Application Publication
(10) Pub. No.: US 2009/0236140 A1
(43) Pub. Date: Sep. 24, 2009

(54) WIRELESS POWER RECEIVER MODULE

(76) Inventor: Mitch Randall, Longmont, CO (US)

Correspondence Address: COCHRAN FREUND & YOUNG LLC, 2026 CARIBOU DR, SUITE 201, FORT COLLINS, CO, 80525, US

(21) Appl. No.: 12/251,428

(22) Filed: Oct. 14, 2008

Related U.S. Application Data
(60) Provisional application No. 60/979,467, filed on Oct. 12, 2007.

(51) Int. Cl. H05K 1/02; H02H 9/00; H01R 13/02

(52) U.S. Cl. 174/268; 361/18; 439/884

(57) ABSTRACT

A charging system comprises a power pad and compatible circuitry on devices to be charged, including contacts in a constellation pattern that interface with conductive strips on the pad to ensure power transfer regardless of orientation. Safety and control circuitry provide spark suppression and short protection.

### CROSS-REFERENCES TO RELATED APPLICATIONS

This application is a nonprovisional application of provisional application No. 60/979,467 filed Oct. 12, 2007, which is incorporated herein by reference.

### BACKGROUND OF THE INVENTION

1. Field of the Invention

The present invention relates to electronic systems and methods for providing electrical power and/or data to one or more electronic or electrically powered devices with a power delivery surface.

2. State of the Prior Art

A variety of electronic or electrically powered devices, such as toys, game devices, cell phones, laptop computers, cameras, and personal digital assistants, have been developed along with ways for powering them. Mobile electronic devices typically include batteries which are rechargeable by connecting them through power cord units, which include transformers and/or power converters, to a power source, such as an electric wall outlet or power grid. A non-mobile electronic device is generally one that is powered through a power cord unit and is not intended to be moved during use.

In a typical set-up for a mobile device, the power cord unit includes an outlet connector for connecting it to the power source and a battery connector for connecting it to a corresponding battery power receptacle of the battery. The outlet and battery connectors are in communication with each other so electrical signals flow between them. In this way, the power source charges the battery through the power cord unit.

In some setups, the power cord unit may include a power adapter, transformer, or converter connected to the outlet and battery connectors through AC input and DC output cords, respectively. The power adapter adapts an AC input voltage received from the power source through the outlet connector and AC input cord to output a DC voltage through the DC output cord. The DC output current flows through the receptacle and is used to charge the battery.

Manufacturers, however, generally make their own models of electronic devices and do not make their power cord unit compatible with the electronic devices of other manufacturers, or with other types of electronic devices. As a result, a battery connector made by one manufacturer will typically not fit into the battery power receptacle made by another manufacturer. Further, a battery connector made for one type of device typically will not fit into the battery power receptacle made for another type of device. Manufacturers make these connectors unique to their own devices for several reasons, such as cost, liability concerns, different power requirements, and to acquire or hold a market share.

However, the proliferation of unique power cords that are not compatible with other devices can be troublesome for consumers because they have to buy unique power cord units for their particular electronic devices and deal with the plethora of different power cords required for their devices. Since people tend to switch devices often, it is inconvenient, expensive, and wasteful for them to also have to switch power cord units, too. Unfortunately, power cord units that are no longer useful are often discarded, which is also wasteful and harmful to the environment. Also, people generally own a number of different types of electronic devices and owning a power cord unit for each one is inconvenient because the consumer must deal with a large quantity of power cord units and the tangle of power cords the situation creates.

### BRIEF DESCRIPTION OF THE DRAWINGS

The accompanying drawings, which are incorporated in and form a part of the specification, illustrate example implementations of the present invention, but not the only ways the invention can be implemented, and together with the written description and claims, serve to explain the principles of the invention. In the drawings:

FIG. 1 is a perspective view of a charging pad, in accordance with the invention, which includes a power delivery support structure and an enabled device to be charged.

FIG. 2 is an isometric view of the charging pad of FIG. 1, showing an array of alternately positively and negatively charged contact strips.

FIG. 3 is a bottom plan view of an enabled device of the invention.

FIG. 4 is a top plan view of a portion of the charging pad of FIG. 1, depicting how several enabled devices are arranged in various orientations for charging on the pad.

FIG. 5 is a block diagram of the charging system of FIG. 1.

FIG. 6 is a top plan view of a representative example wireless charging pad of the invention.

FIG. 7 is a top plan view of several conductive strips of the charging pad of FIG. 1.

FIG. 8 is a diagram showing the “tetrahedron” arrangement of the four contact points of an enabled device, in accordance with the invention.

FIG. 9 is a diagram showing the angular orientation of the contact points of the tetrahedron arrangement of FIG. 8.

FIG. 10 is a bottom plan view of an enabled device of the invention.

FIG. 11 is a cut-away side view of along line 11-11 of FIG. 10.

FIG. 12 is a bottom plan view of an enabled device showing the approximate location of magnets shown in phantom lines.

FIG. 13 is a cut-away side view of a mounted magnet along line 13-13 of FIG. 12, showing example approximate dimensions of a magnet embedded in the casing of an enabled device.

FIG. 14 is a schematic diagram of a four-way bridge rectifier, in accordance with the invention.

FIG. 15 is a schematic diagram of a four-way bridge rectifier, showing the addition of a pass diode.

FIG. 16 is a schematic diagram of the four-way bridge rectifier of FIG. 14, showing an alternate configuration of the active rectifier.

FIG. 17 is a schematic diagram of an aftermarket device enablement.

FIG. 18 is a schematic diagram of a built-in handset enablement.

FIG. 19 is a schematic diagram of a single leg of a bridge rectifier.

FIG. 20 is a schematic diagram of a single active rectifier based on an N-channel MOSFET.

FIG. 21 is a graph showing the transfer function of the control circuit of the present invention.

FIG. 22 is a schematic diagram of a squelching regulator used to drive the supply voltage to the active rectifier of the present invention.

FIG. 23 is a schematic diagram of the power conditioning circuit used to receive power from the power delivery surface of the present invention.

FIG. 24 shows a perspective view of a constellation module of the present invention embedded in a shell-type housing.

FIG. 25A is a top view of the constellation module of the present invention, showing example dimensions.

FIG. 25B is a bottom view of the constellation module of the present invention showing the arrangement of the contact points.

FIG. 26 is a perspective view of the two halves of a gel case for enclosing the constellation module of the present invention.

FIG. 27 is a perspective view of a constellation module showing the wireless power connection assembly.

FIG. 28 is a perspective view of a constellation module showing the gel case and the wireless power assembly.

FIG. 29A is a cut-away view of an example gel case structure and mounting of the constellation module.

FIG. 29B is an enlarged cross-section of a portion of the cut-away side view of FIG. 29A, showing the flexible circuit carrier and flexible circuit of the constellation module.

FIG. 30 is a perspective view of an example power connection assembly, in which the flexible circuit carrier and strain relief are a single unit.

FIG. 31 is a perspective view of an example connection assembly showing the connection between the flexible circuit carrier and the constellation module.

FIG. 32 and FIG. 33 are schematic diagrams that illustrate example circuits for implementing the control and safety system of the invention.

### DETAILED DESCRIPTION OF THE PREFERRED EMBODIMENTS

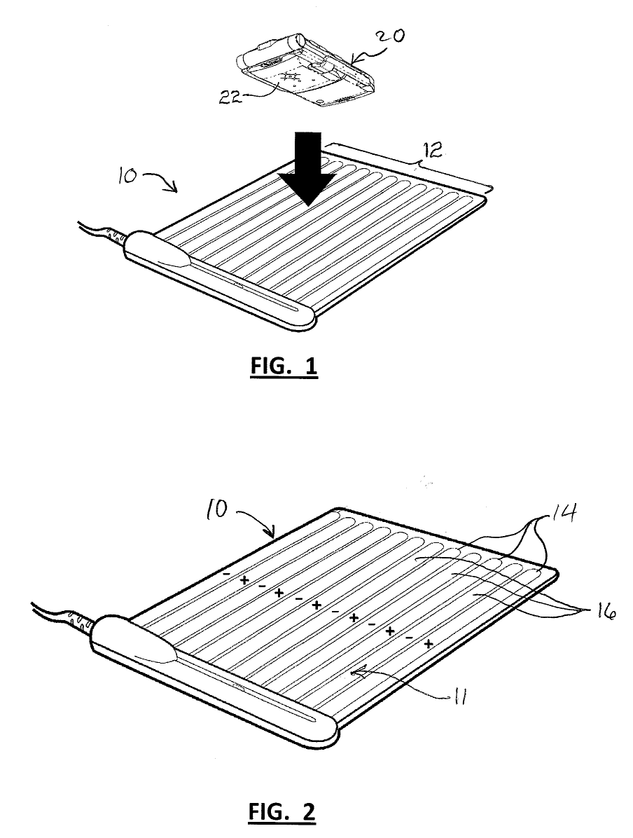

An example charging pad 10 and charging pad-enabled device 20 are shown in FIG. 1. The charging pad 10 transfers power wirelessly, i.e., without a charging adapter cord, to one or more devices 20 resting on it. In this context, the terms “wireless” and “wirelessly” are used to indicate that charging of the device is achieved without a cord-type electric charging unit or adapter, and in the example, is achieved with through electrical conduction through contacts with selective geometry, as described below. Wireless in this context does not mean electromagnetic radiation without electrical conductors. Also, the term “enabled” device is used for convenience to mean an electronic or electrically powered device, for example, cell phone, computer, radio, camera, personal digital assistant, digital recorder and playback device, hearing aid, GPS receiver or transmitter, medical instrument, or just about any other portable device, that is equipped with charging contacts and associated electronic circuitry to enable the device to be electrically charged by the power pad 10 component.

The top surface of charging pad 10 contains an array 12 of contact strips 14, 16 which are energized with low voltage DC so that every other strip, e.g., the strips 14, are positive and the strips 16 in-between the positive strips 14 are negative, as shown in FIG. 2.

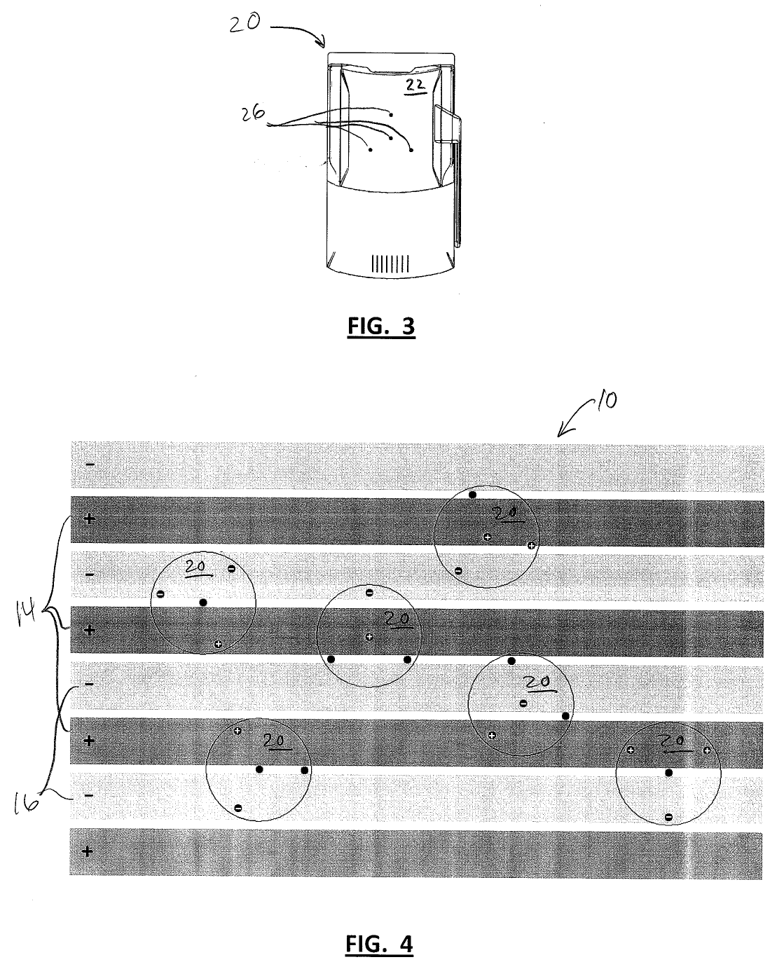

On the underside 22 of the enabled device 20 there are four contact points 26 arranged in a “constellation” configuration 24 as shown in FIG. 3.

The contact constellation 24 on the enabled device 20 and the contact strip array 12 on the charging pad 10 form a geometrically complementary pair with the property that electrical power can be transferred from the pad 10 into the device 20 regardless of the position and orientation of each particular device 20 on the pad. Several orientations are shown for example in FIG. 4 to illustrate this principle, but they are not the only orientations that work.

As can be seen in FIG. 4, no matter where or at which orientation the constellation 26 is set on the pad 10, at least one positive and one negative contact will be made, thus electrical power can be transferred from the pad 10 to the enabled device 20. Power is extracted from the contacts 26 using a rectifier (not seen in FIG. 4), the output of which is equal to the electrical potential of the pad surface 18. Note that the rectifier also inherently prevents the exposed contacts on the mobile or enabled device from being “live” when they are separated or removed from the charging pad 10. In other words, the rectifier between the contacts 26 on the enabled device 20 and the rechargeable battery or capacitor in the enabled device prevents electric current from flowing from the rechargeable battery or capacitor of the device 20 to the contacts 26.

In this architecture, the pad voltage is fixed and independent of the devices 20 resting on the pad surface 18. Each individual device 20 on the pad 10 is responsible for conditioning the electric power from the pad 10 to power that is appropriate for use. This scheme inherently allows for multiple devices 20 of various manufacturers with various power requirements to be charged from the same pad 10.

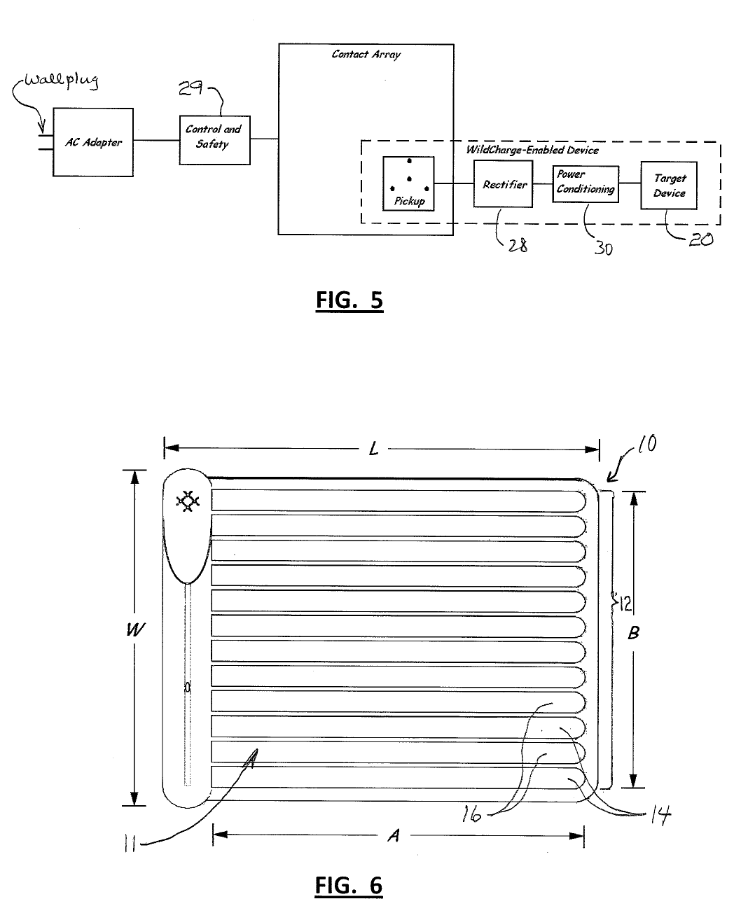

A block diagram of the overall system is shown in FIG. 5. In general, each enabled device 20 contains a pickup constellation 24, a rectifier 28, and a power conditioning circuit 30 to bring power to the target device 20.

A control and safety system 29 renders the contact array 12 benign and safe to the user. The control and safety system 29 energizes the array 12 only when a compliant load is detected. The system 29 senses the presence of non-enabled devices such as keys or hands and instantly safely shuts down.

The control and safety system 29 also has a spark suppression feature. When the pad is delivering full power to a load, there exists the possibility that a metallic object, such as a set of keys, may fall onto the electrode surface and cause a short circuit. In that case, it is undesirable if a spark were to occur. A spark could cause pitting in the metal, it could be a safety hazard, or it could be startling to a user who might then assume the surface electrodes are dangerous.

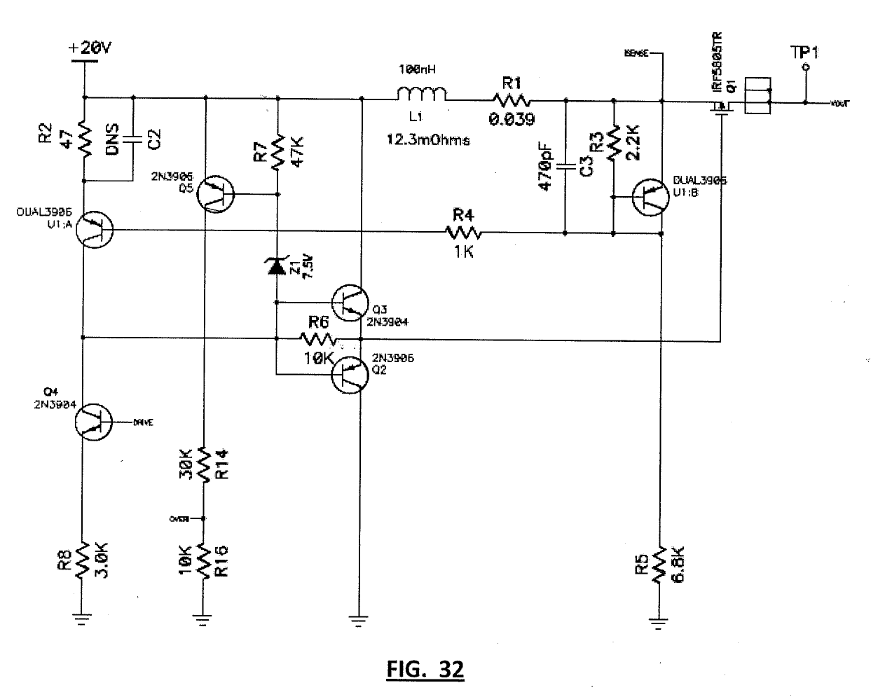

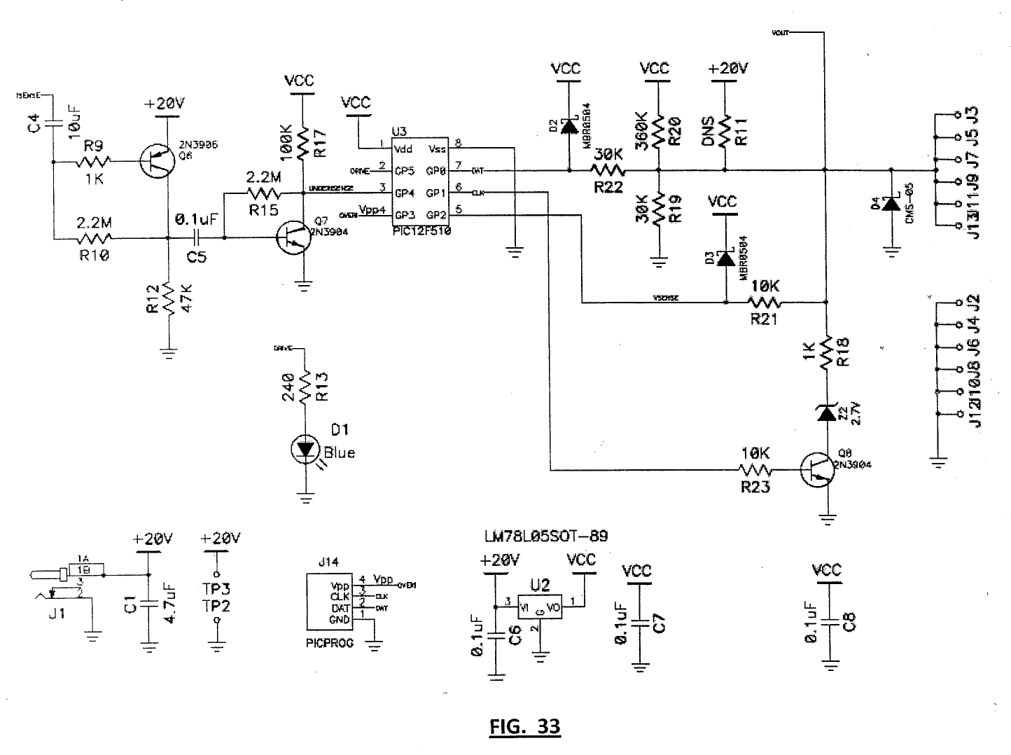

The schematic diagrams in FIGS. 32 and 33 illustrate example circuits for implementing the control and safety system 29. A spark is the result of very high current. Therefore to prevent a spark, the current must be limited. These components, L1, R2, U1, Q2, Q3, and Q4, in the case of a spark, form a high-bandwidth current feedback loop that regulates the output current to a predetermined value until the control system removes drive from the MOSFET Q1.

The bandwidth of the outer feedback loop is very high, but not high enough to prevent the genesis of a spark during the first few tens of nanoseconds of a short circuit event. Once the spark is initiated and the spark gap floods with ions, the spark becomes easier to sustain. It is important that the circuit prevent even the genesis of the spark.

This technique uses the inductor L1 in the source lead of the MOSFET Q1. In the case of a short circuit, the current attempts to rise very rapidly. In this case, a voltage is induced across the inductor that opposes the gate drive and turns off the MOSFET Q1. This reaction is fast enough to prevent the initial spark genesis, but cannot alone maintain spark suppression.

The feedback loop of R2, U1, Q2, Q3, and Q4, forming a high bandwidth current limiting circuit, combined with L1, forming an extremely high bandwidth, but short term, current limiting element, eliminates sparking.

Transistor Q5, and associated components R7, R14, R16, and Z1, detects when the system has gone into current limit and reports this condition to the microcontroller. The microcontroller responds when appropriate to remove drive from the MOSFET Q1. In this way, an unexpected short results in momentary current limit followed by shutdown.

Reduced Output Capacitance: The first spark suppression technique is to reduce the capacitance being presented across the surface electrodes. Stray capacitance is unavoidable, but also discrete capacitors are not used directly across the surface electrodes. Capacitors store energy, and when shorted, they deliver high current to dissipate the energy quickly. The size of the resulting spark is related to the amount of energy stored in the capacitance. A spark is non-linear in the sense that it is easier to sustain a spark than to start one. In other words, the same conditions that sustain a spark may not be sufficient to start a spark. Therefore it is desirable to prevent the initiation of the spark. Capacitance in parallel with R19 will act to initiate a spark where a shorting piece of metal bridges across two adjacent contact strips.

Current Limit Another spark suppression technique is to limit the current in the circuit. R2, U1, Q2, Q3, and Q4 form a high bandwidth current limit circuit. When the current is sufficiently below the current limit, U1 is off and Q4 acts as a switch either supplying or removing drive from the MOSFET Q1. However, when the output current exceeds a predetermined value, U1 begins to conduct acting as an amplifier. The collector of U1A drives the current source created by Q4. The current source created by Q4 has a high equivalent resistance and so the gain of U1A is high. The collector output is coupled to the gate of MOSFET Q1 through a unity gain buffer formed by Q2 and Q3. This feedback loop maintains the output current below a predetermined value. When U1A begins to conduct, the current sourced by Q4 is drawn away from the path to the positive rail through Z1 and the base of Q5. As the conduction through U1A continues to increase, the drive on the base of Q5 diminishes until Q5 is off. When Q5 is off, the voltage at the junction of R14 and R16 drops, signaling to the microcontroller that the loop has become active and that the current is being limited.

Rapid Shutdown: A further spark suppression feature is rapid shutdown of the system. When appropriate, the microcontroller, upon detecting the signal from Q5 indicating current limiting is occurring, can remove drive to Q4, which in turn will remove gate drive from MOSFET Q1. This rapid shutdown can be arranged to occur within 2 μ-sec using readily available microcontrollers. This means that when there is a shorting event, the system can shut down into sleep mode within about 2 μ-sec. If the worst case is assumed that the voltage into an undesired load is 15V, and the predetermined current limit is 1A, then the maximum amount of energy that can be transferred into an undesired load could be 1A*15V*2 μs=30 microjoules.

A number of benefits of the charging system comprising the charging pad 10 and the constellation contacts and circuitry enablement on the mobile devices 20 as described herein are listed in Table 1 and further described in the following section:

TABLE 1

Free Positioning
Simultaneous Charging of Multiple Devices
“One-handed” charging
Home Base -Devices are easy to find
Universal Power Interface
Batteries always topped-off
No more cluttered wires
Travel Friendly - No more lugging bulky chargers
High-Power-Capable
“Green” solution - eliminates multiple AC adapters

“Free positioning” means that a mobile device can rest anywhere and at any orientation on the charging pad surface and receive full, uninterrupted power. There is no need for the user to orient or position the device in a specific way in order to receive power.

The charging system inherently allows many devices of differing power needs to rest on and receive power from the pad at the same time.

The wireless power technology of the system makes powering and charging a device simple. A user can effortlessly set a device on the pad without any particular thought or effort as to orientation or hook-up to fully power and charge the device.

The charging system is a universal power interface meaning that different mobile devices can share the same power source. This greatly simplifies the lives of users who typically have several mobile electronic devices, each with their own AC adapter.

Having a universal power source that is so easy to use results in the system being accessed more frequently. This, in turn, means users experience their batteries being more fully charged. Users can use more power-hungry features of their devices given the more frequent charging that naturally occurs.

Users will tend to use the charging pad more often because of its convenience and other benefits. This has the side effect of creating a “home base” for devices where they can usually be found.

The charging system also eliminates the tangle and clutter of the multitude of wires needed to power and charge the number and variety of devices many users typically have.

The charging system eliminates the need for a plethora of AC adapters—one for each mobile device. Instead, just one charging pad can supply the power needs of many mobile devices.

The charging system is also capable of economically bringing the convenience of wireless power to higher power devices such as laptop computers, lamps, portable televisions, razors, hair care devices, power tools, and many others as well.

Finally, the present invention eliminates the array of separate AC adapters that a typical consumer needs to power and charge all their devices. With the charging pad 10 available, the AC adapters that now come with the purchase of almost every new device, even of the same type, are no longer needed. In a typical home several of these adapters can be found plugged in, but not in use, wasting energy. When the devices are expired, such typical adapters become virtually worthless and are destined to end up in landfills, so eliminating the need for so many AC adapters by use of the charging system described herein has environmental advantages as well as reducing the cost of purchasing mobile devices.

The architectures promoted by the charging system are useful to the philosophy of providing a universal power delivery interface, where one geometry and electrical specification can satisfy the power needs of a broad range of devices. This charging system has a straightforward architecture that allows interoperability and graceful fault tolerance among the many devices that share the infrastructure. Therefore, users are able to place any of their enabled devices on any available charging pad surface to get power.

In a fully installed infrastructure, many power delivery pads will exist with varying power handling capabilities. They may be in homes, cars, offices, hotel rooms, conference rooms, airplane seat trays, coffee shops, hospital rooms, medical and dental offices, etc., so that users and customers of those places and facilities can charge their devices conveniently. Pads with multiple power handling capabilities exist simultaneously. For example, there may be three power capabilities present throughout the infrastructure: 15 W pads, 65 W pads, and 120 W pads. At the same time, many enabled devices such as cell phones, cameras, laptops, medical equipment, power tools, etc., exist covering a broad range of power input needs from 1 W to 120 W.

All of these different requirements may be transparent to the users. Any number of devices can be placed on and charged by any given pad, provided that the total power requirement does not exceed the rating of the pad. This means, for example, that one can operate his or her laptop computer on a pad while also charging a cell phone and powering an enabled coffee mug on the same pad.

To achieve full interoperability between many varied devices 20 and various charging pads 10 intended for specific power handling requirements, it is desirable to establish a consistent geometry across applications. The dimensions of the constellation pattern 24 of the contacts 26 (see section 4 below) was chosen to address the needs of small, low-power devices such as digital music players as well as larger, more power-hungry devices such as laptop computers and desktop lamps. Across all platforms, the dimensions of the contact strips and the pickup constellation have been standardized.

Within the specification of the charging system, a device 20 can be enabled to determine the power handling capacity of the pad it is resting on. Power management occurs in three tiers within the specification and may be characterized or keyed by output voltage and/or digital communications, for example:

TABLE 2

| | | | Digital Power |
|---|---|---|---|
| Tier | Power Output | Output Voltage | Management |
| 1 | 0-30 Watts | 11 V-16 V | No |
| 2 | 30-60 Watts | 18 V | Optional |
| 3 | 60 Watts and above | 19.5 V | Recommended |

These example tiers reflect various usage models. Tier 1 power pads may be designed primarily for charging multiple low power hand held devices. Typically these devices consume 2-5 W. In this case, power management is inherent to the surface area of the pad. A typical cell phone occupies about 8 in² of pad area, and consumes about 3 W of power or about 0.38 W/in². As an example, a 15 W may have about 38 in² of active area, which corresponds to approximately 14.4 W of cell phone usage.

Tier 2 power pads may be designed for one medium device and numerous smaller devices as in a travel application. In this usage model, for example, a single laptop could be charged or used along with perhaps a cell phone and music player. In this example, power management may correspond or be provided by a purposely limited charging surface area, given the assumption that only one laptop or other such larger device can fit in the given area. Digital power management is optional but not mandatory in this tier and can be included for product differentiation (good/better/best).

Tier 3 power pads may be designed for multiple high-power devices. In this case an unknown number of high power devices may be present and the surface area is not likely to limit usage in a predictable way. This would be the case, for example, in a conference room application or coffee shop table situation where one large pad may cover most of the surface area of a table or where multiple power tools of widely varying sizes may be used. In this case, digital power management is recommended. A digital communication scheme optionally provides digital power management communications between the pad and each device in tier 2 and tier 3.

Tier 1 applications offer the most straightforward and cost effective implementations. It is convenient that they also comprise the largest fraction of consumer applications.

Voltage discrimination is used as a straightforward method of distinguishing the first level of power management. For example, a laptop computer requiring 85 W would not need to engage the pad 10 if it did not detect at least 19.5V on the pad. Likewise a 40 W desk lamp could enable only if the pad voltage detected was 19.5V or greater. A low power device (less than 5 W), on the other hand, can be made to work on a pad 10 from any of the three tiers.

This method of power management can handle a large number of cases comprising the largest usage model while keeping the system complexity and cost down.

Digital power management becomes more important for pads 10 that can supply a larger amount of power and/or have a greater area. In this case communications are established between the device and the pad. The device and pad then share information such that devices throttle back or turn off to prevent attempting to draw more power than the pad can supply. Digital power management is beyond the scope of this document and will not be discussed further herein.

Situations may arise where the total power required by all the devices 20 on a pad 10 exceeds the pad's power capacity. This condition is part of the tier 1 power management scheme and should have a predictable response. For example, the pad may shut down and periodically attempt a restart. Until the power requirement condition changes (e.g., a device is removed), devices 20 on the pad 10 will not receive power. This fault condition can persist indefinitely.

The pad 10 may also employ an LED, power meter, LCD screen, or other type of user display to indicate that an overload condition is present.

Charging pads 10 provide a surface of conductive strips of specified width and array spacing to mate with the standard pickup or contact geometry, e.g., the constellation shown in FIGS. 3 and 4 (see below). In general, the overall size and shape of a pad 10 can vary, but the width and spacing of the strips 14, 16 must remain the same in order to deliver power to a particular contact 26 arrangement and size.

In a fully installed infrastructure, charging pads 10 of many styles and power handling capabilities exist to support an array or variety of mobile devices 20. To facilitate such an infrastructure, each mobile device 20 uses a pattern of contacts designed to compliment the same basic surface electrode geometry. Further, every pad 10 uses identical surface electrode dimensions and geometry. The electrical characteristics of both the surface electrodes and the mobile device enablement ensure the maximum interoperability and predictable fault tolerance across a broad spectrum of applications.

Some example overall dimensions for a 15 W wireless charging pad are shown in FIG. 6 and listed in Table 3.

TABLE 3

| | |
|---|---|
| L | 7.908″ |
| W | 6.500″ |
| A | 6.790″ |
| B | 5.698″ |

The dimensions A, B of an active surface may vary depending on the length and number of strips in the particular design. However, for a particular set of pads 10, it is desirable that every charging surface will maintain the same specified width and spacing of the strips in order to interface with a particular constellation pattern and size of contacts 26 used on a group of various mobile devices 20.

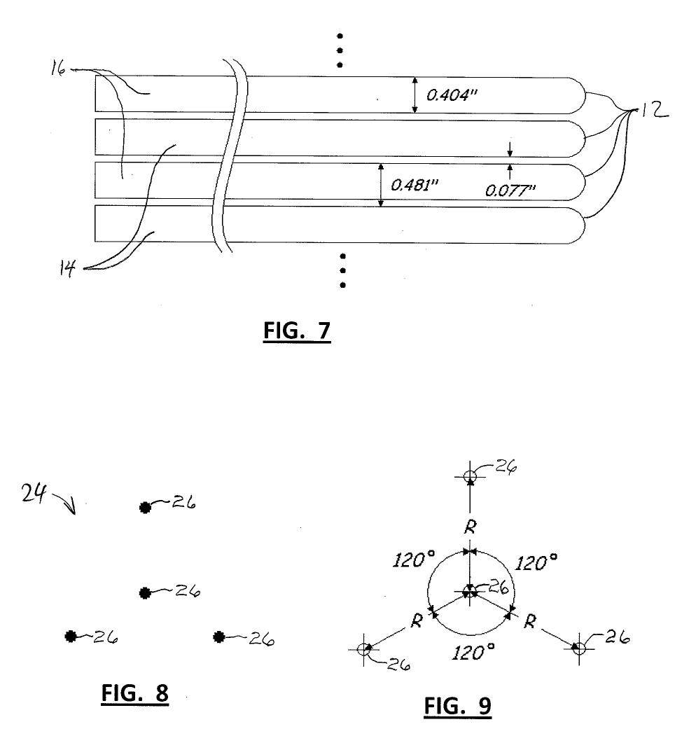

The surface 11 of the charging pad 10 comprises conductive strips 12 arranged parallel to one-another in an array with a specific width and spacing. The standard dimensions of the metal strips are as shown in FIG. 7.

Because the width and spacing of each strip must be fixed, the width B of the active area in an example implementation is given by:

B=0.48125N−0.077

Note that for the purpose of this calculation, the array spacing used in this example is 0.48125″, which is the exact value of the example design.

The overall surface 11 of the charging pad 10 is preferably smooth and flat or have a gentle curve over all of the strips 14, 16 and intermediate spacings between them to insure that the enabled device 20 seats properly when resting on the surface 11, regardless of where any of the particular contacts 26 may land on the surface 11. Regarding flatness, the performance is more sensitive to ridges or steps rather than an overall smooth curvature of the surface 11. For this reason, it may be desirable to take care that the surface 11 does not have a significant step between the surface of each strip 12 and the surface of the gaps between the strips 12.

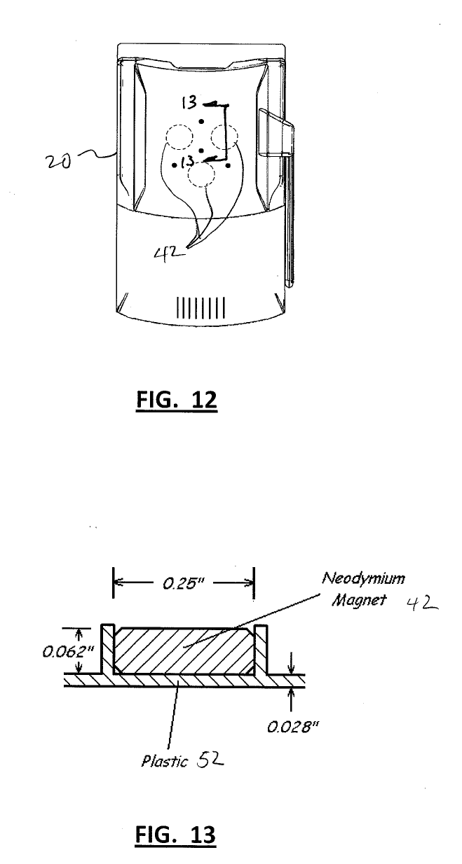

Polished stainless steel strips with a bright nickel plate make good example strips 14, 16. The 430 stainless steel is used to ensure high product durability and corrosion resistance. The nickel plate ensures reliable electrical contact performance over time as well as a mirror-like finish. The 430 stainless steel strips are 0.015″ thick to provide adequate conductivity at the rated power of 15 W. This metal is also ferromagnetic, and at this thickness allows the magnets 42 (FIGS. 12 and 13) in the enablements to pull the device 20 firmly to the surface 11 of the pad 10. Other materials may be used to achieve conductivity, contact reliability, and magnetic attraction, as would be known to persons skilled in the art, once they understand the principles of this invention. The backing material used in the pad 10 is non-conductive and may take various forms, such as an engineered thermoplastic, for example.

The contact strips 12 are energized with low voltage DC. Depending on the application, the DC voltage can range in one example from 11V to 19.5V. The polarity of the voltage is positive on every other strip 14 and negative on the strips 16 in-between (see FIGS. 2 and 7). The negative potential is defined as ground (0V), although is not necessarily connected to Earth ground.

During operation, the DC voltage may occasionally be interrupted for a brief period (10 μs). For this reason, it may be advantageous for the pickup electronics to use a capacitor to store energy during this interval to avoid causing a drop-out in the supply of power to the target device 20.

The system controller supplies power to the contact strips when appropriate and senses fault conditions. Typically the system controller provides the following functions:
a) If no device 20 is resting on the pad 10 for more than 3 seconds, DC power will be removed from the contact strips.
b) If an enabled device 20 is resting on the pad 10, DC power will be applied to the contact strips 12.
c) In the event an object placed on the pad 10 (such as a set of keys) short-circuits the pad 10 during normal operation, the control and safety circuit prevents a spark from occurring. Further, the controller will take the system into a sleep mode until the short is removed.
d) In the event an undesired load such as a hand or a liquid spill is present on the pad, DC power is removed from the contact strips. The control and safety circuit is used to detect such conditions.
e) An LED indicates the status of the pad. On=active, Off=sleep.

By regulatory agency standards, the low voltage present on the contact strips 12 is safe. Further, the potential used is so low, that even without the system controller, few people could even detect it. The system controller takes this several steps further to create a power source that is virtually imperceptible and far safer. To put it into perspective, a 9V battery is far easier for a person to sense, and much less safe than the pad 10.

A specific geometric pattern of contacts 26, or constellation, is used to receive power from the charging pad 10. The constellation geometry is such that regardless of the orientation and position of the constellation relative to the contact strips 12, a circuit can be closed and power can be transferred (see Section 1).

The constellation geometry and the surface contact geometry form a matched pair to provide power transfer at any orientation of the constellation or device 20 with respect to the pad 10. For the parallel contact strip geometry of this architecture, there is more than one complimentary constellation that insures power transfer. The scope of this document will be limited to one such constellation, loosely referred to as the “tetrahedron” for its resemblance to the top plan view of a tetrahedron. The “tetrahedron” constellation 24 configuration of contacts 26 is shown in FIG. 8.

In a fully installed infrastructure, charging pads 10 of many styles and power handling capabilities may exist to support an array of mobile devices 20. Any mobile device 20 may be placed on any subject charging pad 10. To facilitate this, each mobile device 20 uses the same size and pattern of contacts 26. (Note that other patterns can be used. Nevertheless, the point remains that all patterns are designed to compliment one standard geometry and dimension of surface electrodes). In addition, each mobile device 20 contains circuitry to appropriately handle a range of input voltages from an array of compliant power delivery surfaces (pads).

FIG. 9 shows the relationship of the four contact points comprising the constellation 24. The dimension R in this example is 0.385″.

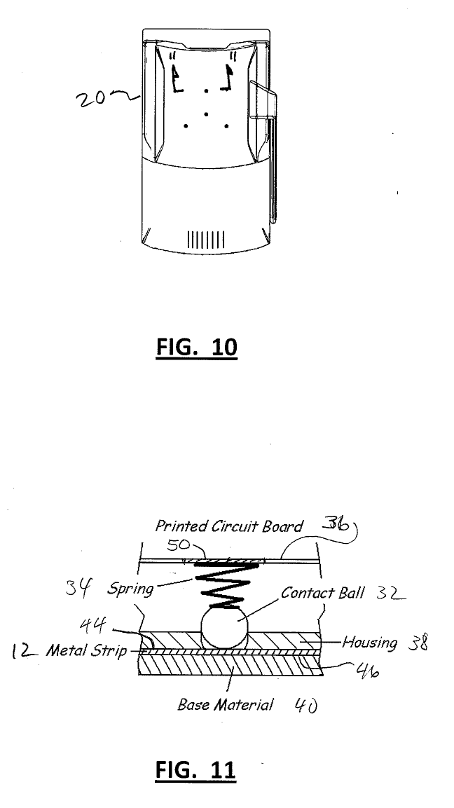

An example contact stack of each contact point 26 is shown in FIGS. 10 and 11. A ball bearing 32 is resting in contact with a metal strip 12 of the pad 10. The housing 38 of the enabled device 20 is being held to the pad 10 by magnets 42 (FIGS. 12 and 13) pulling the printed circuit board 36 to the surface 44 of the metal contact strip 12. A backing on or portion of the printed circuit board 36 makes contact with the spring 34 and creates the opposing force pressing the ball 32 onto the surface 44 of the metal contact strip 12.

It is most desirable that the contacts 26 meet the surface 44 at a point or nearly a point. It is also required that the contact 26 does not bridge the distance between strips (e.g., 0.077″) to prevent a short circuit between the strips 14, 16. For example, the contacts 26 can be spherical, as shown in FIG. 11. It has been found that 2 mm ball bearings are an excellent choice for their durability and low cost.

The housing 38 of the device 20 should hold the contact ball 32 so that it protrudes slightly, for example, about 0.020″ proud of the bottom surface 46 of the housing 38 when the device 20 is not resting on a charging pad 10. This example protrusion dimension has been found to be sufficient to allow contact in the presence of reasonable debris on the surface of the pad 10.

The exit hole 48 of the housing 38 should be round and held to a reasonable tolerance so that when the ball bearing 32 is seated, it forms a seal to prevent contaminants from entering the housing 38.

The contact balls 32 are brought in contact with the surface 46 with conical springs 34. In addition, the springs 34 carry the current between the ball bearing 32 and the printed circuit board 36. The springs 34 are conical to allow them to collapse on themselves to keep the overall stack size as small as possible. Nickel plated beryllium-copper is a suitable material for the springs 34, although other electrically conductive materials can also be used. The nickel plating provides excellent contact performance, while the beryllium-copper works well for springs yet is not magnetic (important for assembly when magnets are present).

The contact pads 50 on the printed circuit board 36 carry the current picked up by the ball 32. For ease of assembly, the spring 34 need not be soldered to the contact pad 50, rather the pad 50 and spring 34 can connect through direct contact. It is recommended that the printed circuit board pads 50 be ENIG plated (Electroless Nickel Immersion Gold) for reliability.

Proper operation of the invention requires that the contact constellation 24 rest squarely on the pad surface 18. The frame holding the contact constellation 24 should be rigid so that it does not distort under the pressure of the presumed magnetic force. Distortion of the material translates to rocking motion of the device 20 depending on the design.

The contacts 26 may be nickel plated with a layer at least 50 microinches thick. This will provide the good reliability and low contact resistance over the life of the product.

Spring exertion of a force of a contact 26 on the surface 11 of at least 3 oz. is usually sufficient to insure reliable contact performance over the life of the product. Given that there are four contacts 26 in the constellation pattern, this means the total force is 12 oz. For small devices, gravity alone may not be sufficient and magnets, for example, the magnets 42, as shown in FIGS. 12 and 13, may have to be employed.

In some cases the weight of the target device 20 may be sufficient to allow generating at least 3 oz. of force on each contact. If the target device 20 is just over the required 12 oz., then it may be helpful to align the center of the “tetrahedron” with the device's center of gravity to prevent rocking or tipping.

For target devices 20 weighing much more than 12 oz., aligning the center of gravity with the center of the “tetrahedron” is much less important.

FIG. 12 shows a typical application designed to achieve sufficient contact force. In many cases magnets 42 are employed to augment the contact force to attain the minimum recommended level of 3 oz. per contact ball 32. The attractive force of the magnet 42 can also be exploited to stabilize a mobile device 20 in automotive applications. Devices can be made to support their own weight and cling to a vertical surface, such as a refrigerator door, or to a pad 10 mounted with its surface 11 oriented vertically or at any angle from horizontal.

Note that the exact position of the magnets 42 on the bottom surface 22 of the device 20 is not critical, but the attractive force transmits through the enclosure to create force on the springs 34. It is also desirable that the face in contact with the pad surface 18 does not distort due to the force exerted by the magnets 42.

In FIG. 12, the phantom-lined circles indicate example locations of three magnets 42 retained by the plastic cover 52 of the device 20. Three neodymium magnets 0.25″ in diameter and 0.062″ thick can provide the necessary magnetic attraction to the ferromagnetic contact strips 12 of the charging pad 10, although other materials and magnets can be used. For example, the cover 52 itself could comprise a composite magnetic material.

The neodymium magnets used in one embodiment of the invention create a magnetic field that can affect the operation of certain electronic components such as inductors, audio speakers, motors, and magnetic disk drives. Care should be taken to insure that the magnets are separated from such devices, or that the devices are functioning properly in the presence of the magnets.

Investigations have shown that an economy grade neodymium magnet of the specified thickness and diameter, and separated from the outer surface by the specified amount will not cause damage to magnetic stripes such as is found on credit cards. However, hotel room key cards made from low grade materials are notorious for being easily erased by a number of consumer electronics devices and may be susceptible to erasure by the magnets 42.

In some applications it may be desirable to increase the amount of force holding the device onto the power delivery surface or other metallic surfaces. To accomplish this, one option is to use more powerful magnets or to reduce the distance between the magnet and the outer surface. In either case, the peak external magnetic fields are being increased. In this case, the designer may want to verify that the increased magnetic fields do not damage credit cards.

Another option is to use more magnets. More magnets will increase the force without increasing the peak field strength. It is the peak field strength that is potentially damaging to such things as credit card magnetic stripes. Most hand-held devices can be easily attached to a refrigerator door with 4 or 5 magnets of the type as shown above.

As described in the first section, and as shown in FIG. 4, the contact points 26 of the constellation 24 come in electrical contact with the parallel contact strips 12 of the charging pad 10. The geometries insure that at least one constellation contact point 26 will come in contact with a positive pad contact strip 14, and another constellation contact point 26 will come in contact with a negative pad contact strip 16.

The following are top-level electrical specifications for an example compliant mobile device 20.

Electrical Specifications

| Symbol | parameter | conditions | min | typ | max | unit |
|---|---|---|---|---|---|---|
| Vin | Input Voltage | | 11 | | 20 | V |
| Iin | Input Current | Vin = 11 V, Pin <15 W | | | 1.4 | A |
| | | Vin = 15 V, Model PA- | | | 1 | A |
| | | 250-C Pad (15 W) | | | | |
| Pin | Input Power | Vin = 15 V, Model PA- | | | 15 | W |
| | | 250-C Pad (15 W) | | | | |
| Td | Turn-On delay | | 100 | | | ms |
| Cr | Rectifier Capacitance | | 1 | 5 | 150 | μF/W |
| Ci | Input Capacitance | | | | 500 | pF |

It is not known a priori which constellation contact point 26 will be positive, and which will be negative. Further, multiple constellation contacts 26 could come in contact with a given polarity contact strip.

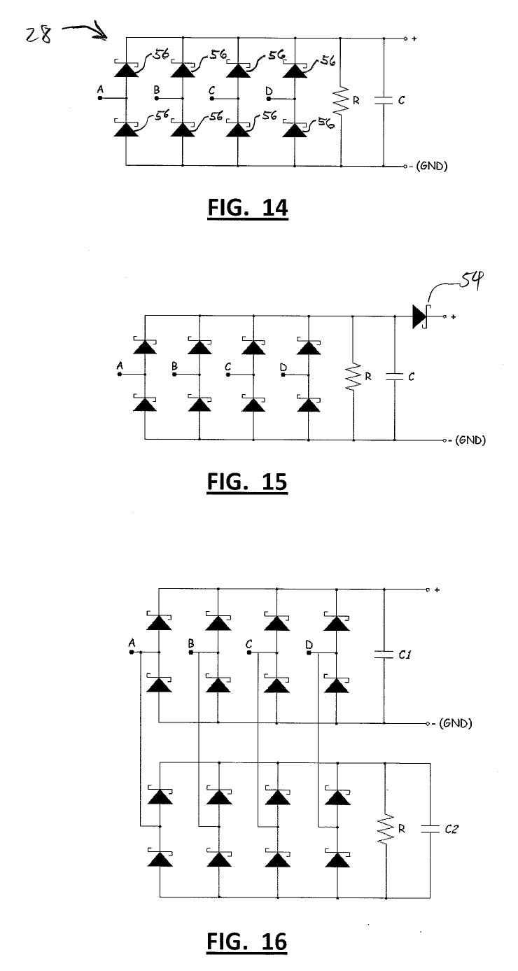

A four-way bridge rectifier 28 as shown in FIG. 14 is used to commutate the constellation contacts appropriately to positive and negative rails. Schottky diodes may be used in the rectifier for good efficiency, but other kinds of diodes can be used. FIG. 14 also shows a resister R and capacitor C which will be discussed in further detail below.

The diodes 56 should be sized to adequately handle the rated current over all input voltage conditions. In a typical cell phone application, the maximum input power is approximately 2.5 W. The pad voltage can range anywhere from 11V to 19.5V. At 11V the maximum diode current would be 2.5/11=227 mA.

The control and safety circuit 29 detects enabled devices 20 and activates the charging pad 10. For this detection to work properly, the rectifier 28 may need a resistor R across the output of the rectifier 28. The value of this resistor may be, for example, about 10K ohms for good operation.

In some applications, the output of the bridge rectifier 28 of FIG. 14 may be back-biased by the circuit it is powering. What is meant by this is that when the device 20 is not resting on the charging pad 10, the voltage across resistor R is not zero.

This situation is problematic for two reasons. Firstly, battery current will flow through the 10K resistor reducing battery life. Secondly, back bias will prevent the start circuit from properly detecting the device 20 on the pad 10.

There are two example solutions for this problem. The first example is by the addition of a pass diode 54 as shown in FIG. 15. This simple solution has the disadvantage that the efficiency is degraded by the additional loss of the pass diode 54. In a typical cell phone application, the additional loss may be on the order of 90 mW.

The second example technique is shown in FIG. 16. Here a separate rectifier is used for compatibility with the start circuitry, yet no additional loss is inserted in the circuit. The additional diodes used can be sized for very low current as they are not involved in power transfer. The capacitor C2 is required and should be a value of 2.2 nF.

As mentioned earlier, the power on the charging pad 10 will occasionally be interrupted for about 10 μs. An energy storage capacitor C is helpful to prevent the rectifier output voltage from dropping out. The capacitance value can be computed as C=PK, where P is the maximum power required by the device, and 1 μF/W<K<150 μF/W. A good value for K is about 5 μF/W corresponding to a maximum droop of about 180 mV.

A startup delay may be beneficial in each enablement to allow the pad voltage to stabilize at the nominal value before full power is delivered. The startup delay may be, for example, 100 ms or longer. Also, the turn-on delay spec should be met even after a short, for example, three second, loss of power.

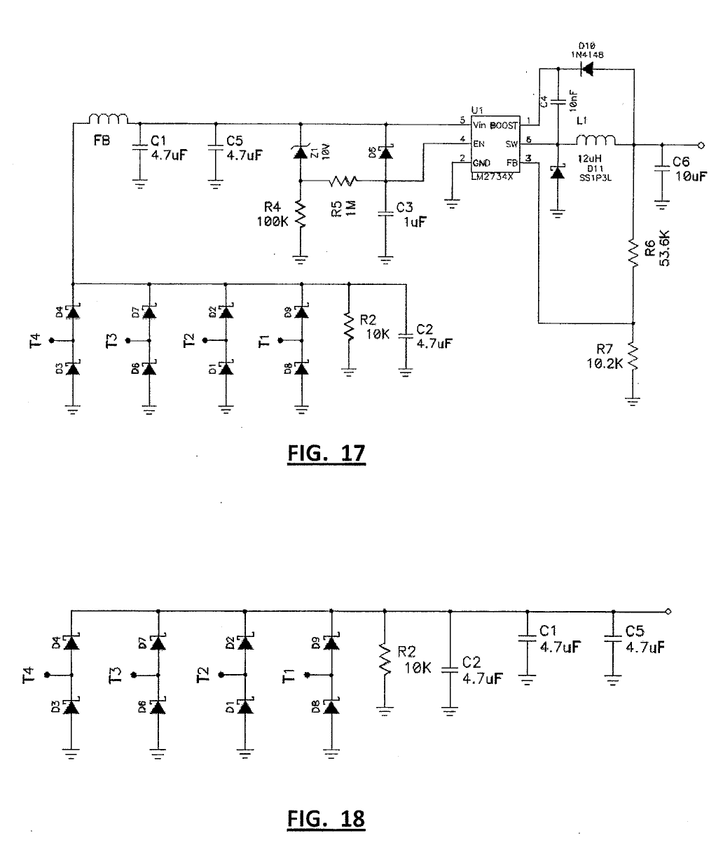

The schematics in FIGS. 17 and 18 represent typical implementations of receivers for picking up power from a pad 10. An example aftermarket device enablement schematic generating 5V at 1A is shown in FIG. 17. T1, T2, T3, and T4 are the contact point connections. The input from the contact points is rectified and filtered before being input into the switching regulator IC. Z1, R4, R5, and C3 form the turn-on delay circuit. D5 ensures the turn-on delay circuit resets quickly in case the power drops out momentarily. L1, D11, and C6 form the buck output circuit for the LM2734. This implementation assumes the target device operates from 5V DC at up to 1A.

An example built-in handset enablement is shown in FIG. 18. In this case the contact points are connected to the input of a bridge rectifier. The handset design-in implementation assumes that the input circuitry of the handset is capable of handling up to 20V DC. If that were not the case, a regulator as shown in the aftermarket device enablement schematic (FIG. 17) could be employed.

In certain applications the current requirement is very high. As an example, assume a 20V pad 10 is delivering power to a 100 Watt laptop computer. In this case the current drawn would be 5 Amps. A commercially available Schottkey diode rated at 5A has a forward voltage drop of about 0.55V. At least two such diodes would have to conduct for there to be a closed circuit. In this case, the two diodes dissipate 5.5 W, which is a relatively high loss resulting in possible cooling problems.

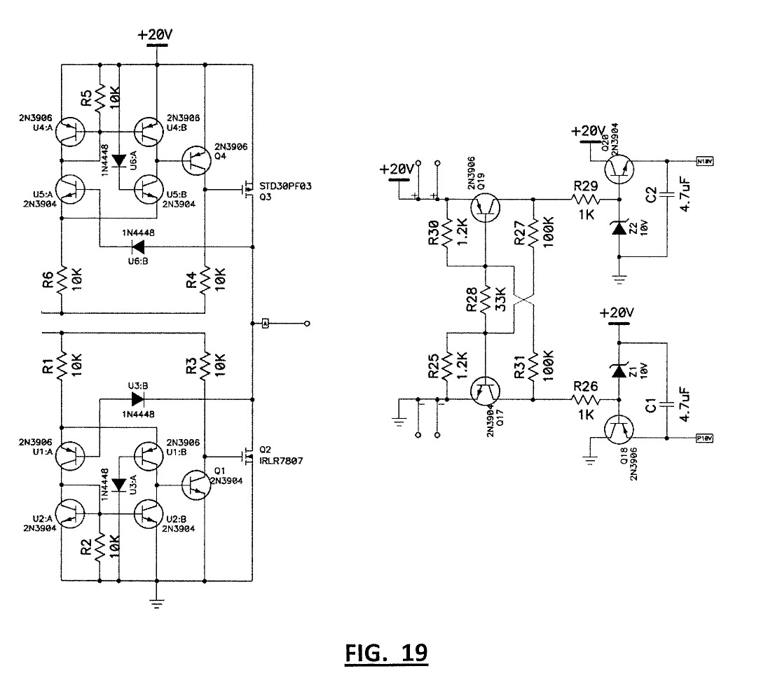

For the purpose of efficiency and thermal management, an improved diode is desirable. FIG. 19 shows a single leg of an example bridge rectifier with two active diode based FET switches and polarity detectors.

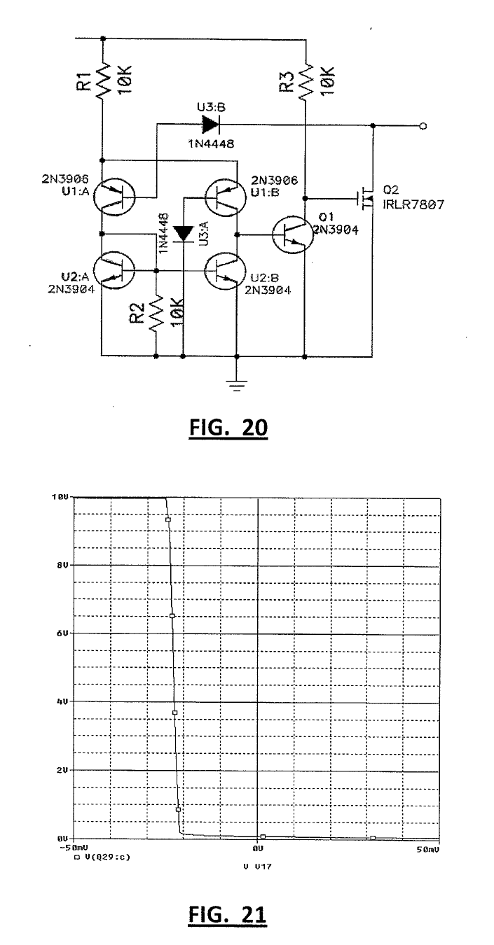

FIG. 20 shows an example single active rectifier based on an N-Channel MOSFET. In this example embodiment, U1A and U1B form a difference amplifier comparing the input voltage Vin (the drain of Q2) to ground. Each base is tied to diodes U3 to stand off the voltage Vin when the active diode is reverse biased (Vin positive). U2A and U2B further amplify the difference signal as a current mirror. The output of the difference amplifier is at the collector junction of U1B and U2B. The difference amplifier output drives inverting transistor switch Q1 which drives the N-Channel MOSFET.

The overall operation of this example active rectifier is as follows. Positive voltages Vin on the drain of MOSFET Q2 cause transistor U1A to turn off and U1B to turn on. The diminished current at the collector of U1A is reflected to the collector of U2B through the current mirror U2. Therefore, the current at the collector of U1B will be diverted to the base of Q1 thereby turning off the gate of MOSFET Q2. As a result, no current will flow through the drain of Q2.

A negative voltage on the input Vin will turn on U1A and turn off U1B. The increased current at the collector of U1A will be reflected through the current mirror U2 to the collector of U2B. Base drive to Q1 will be off, and the voltage at the collector of Q1 will be high, turning on MOSFET Q2. Therefore, current will flow through the drain and source of Q2.

The net result is that positive voltages Vin do not draw current, while negative voltages Vin draw current, just as an ideal diode should function.

The active rectifier control circuit performs the function of a high gain amplifier. Because of the unique topology, this configuration is ideally suited to drive the MOSFET as an active diode.

The control circuit monitors the voltage across the MOSFET Drain and Source. If the voltage is positive (for the N-Channel active diode), then gate drive is removed. If the voltage is negative, then full gate drive is commanded. When at zero volts, the gate drive should be off. This prevents a lock-up that can occur if there is a slight offset in the system. If an undesirable offset is present, then the device may stay on with positive voltage. If the device stays on, then it will hold the voltage low, which will maintain the device in a locked condition.

The control circuit has an input imbalance as part of current mirror intrinsic asymmetry. This is taken advantage of to create a unique and simple design topology. The asymmetry of the current mirror is further exaggerated by R2.

The transfer function of the control circuit is shown in FIG. 21.

The schematic of FIG. 20 shows a high-side and low-side active diode connected to a single input.

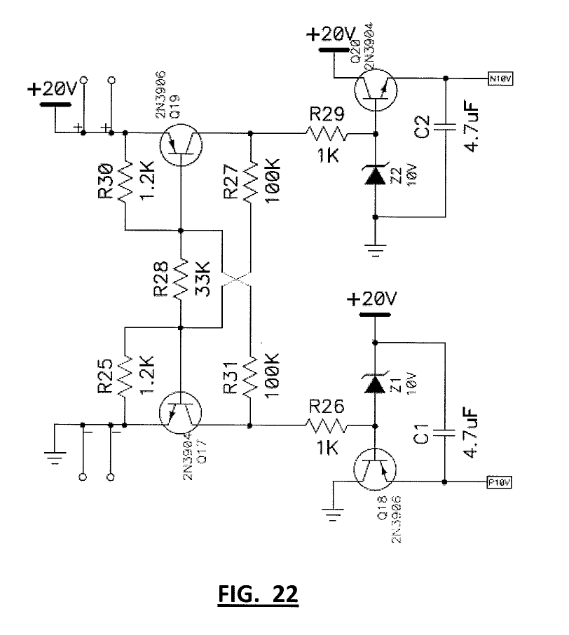

FIG. 22 shows an example squelching regulator that can be used to drive the supply voltage to the active rectifier. By squelching it is meant that the regulator does not provide a substantial output until the input (rectified voltage) exceeds a threshold. An overview of its operation is as follows. When with no input voltage on A, B, C, or D—the bridge rectifier input—the rectified output will be zero. In FIG. 22 the rectified output is delineated as “+20V” and the ground symbol. Here, it is worth noting that if no voltage is applied the control portion of the active regulator of FIG. 21 (N10V), then the MOSFET Q2 is left off. In this case the intrinsic diode within the MOSFET becomes part of the rectifier. The intrinsic diode is in parallel with the active diode. When the voltage N10V become great enough, the active diode begins to function and the intrinsic diode will not conduct.

In the operation of the squelching regulator, as the voltage increases at the rectifier output (“+20V”), a voltage develops across R25 and R30. At some threshold voltage on the input, the voltage across R25 and R30 will cause the bases of Q17 and Q19 to conduct. As Q17 and Q19 begin to conduct, the voltages across R25 and R30 will become greater due to the positive feedback resistors R31 and R27. This hysteresis causes the switches to rapidly saturate. With both Q17 and Q19 saturated, simple shunt regulators with associated buffers turn on to regulate 10V above ground and 10V below the positive rail. These voltages define the maximum gate drive of the active rectifier control circuit.

Included below is a glossary of terminology used in this application:
Constellation The geometric arrangement of a collection of contact points.
Constellation Module A device (“black box”) containing all the necessary technology to pick up power from a pad and generate a useable, regulated output. The Constellation Module standard unit is a standard unit that can be used in a number of device enablements.
Contact Strips The electrodes on the surface of a pad.
Device Shorthand for an electronic unit capable of receiving power from a pad. In context it implies the unit contains contact points and the necessary support circuitry to receive power from a pad.
Enabled Device An electronic unit capable of receiving power from a pad.
Enablement The components, circuitry, contact points, and mechanical casement to attach to a device and provide power to it as received from a pad.
Pad The surface and support structure with electrodes upon it and upon which devices rest to receive power.
Surface contacts The set of electrodes comprising the surface of the pad.
Swim lanes The set of electrodes comprising the surface of the pad. This term is more descriptive as the electrodes resemble swim lanes in an Olympic pool.
Target Device The electronic unit which is selected to be energized by wireless power received from the pad.
Unintended Load An object other than one intended to receive power from a pad with a finite impedance.

The charging system comprises a pad that transfers power wirelessly to one or more devices resting on it. This is achieved through electrical conduction and the use of geometry. An example charging pad and device is shown in FIG. 1.

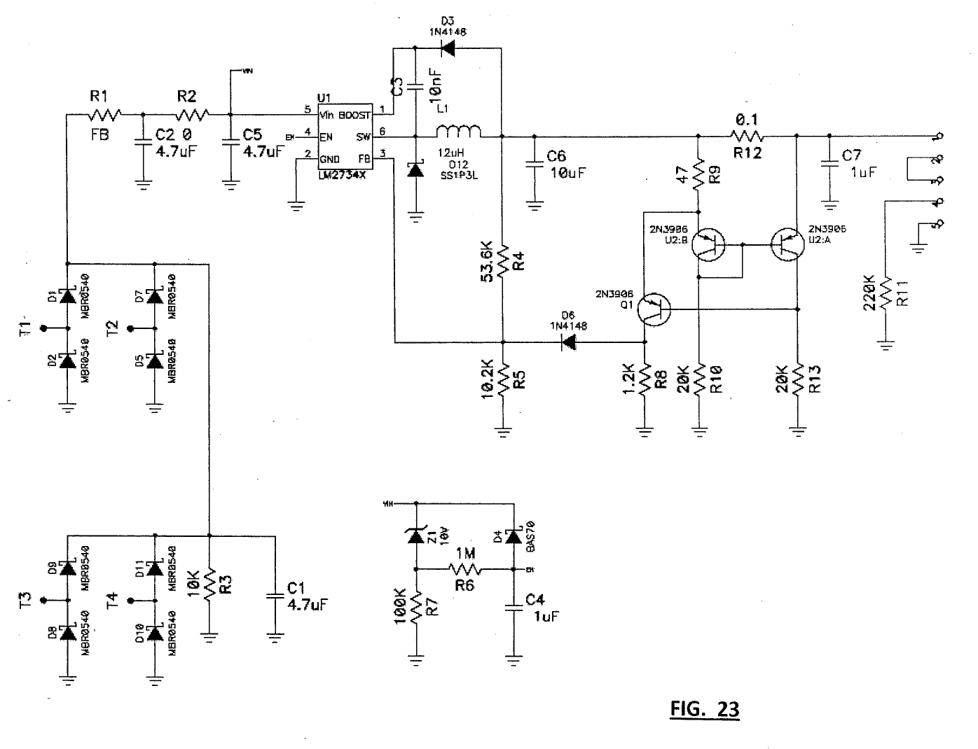

FIG. 23 is a schematic (“Generic DC/DC Adapter Circuit”) showing the power conditioning circuit used to receive power from the power delivery surface. The four contact points forming a “tetrahedron” shape are connected to the points T1, T2, T3, and T4. The bridge rectifier formed by D1, D2, D5, D7, D6, D9, D10, and D11, together with resistor R3 and capacitor C1 forms the required turn-on network to alert the system controller, with associated sensing functions described above, that a compliant load is present on the power delivery surface. The output of the bridge rectifier flows through Ferrite Bead R1 and is further filtered by C2, R2, and C5. An integrated buck switching converter chip, the LM2734, is used to regulate the predetermined input voltage to a predetermined output voltage. In this case the output voltage is set at 5.0V by R4 and R5. A turn-on delay circuit is formed by R7, R6, C4, Z1, and D4. This prevents the regulator from operating until the input voltage has stabilized using the assumption that within 240 ms the input voltage will have stabilized. A current limiting circuit comprising R8, R9, R10, R12, R13, D6, Q1, and U2 is connected to the output to both protect the circuit and to mimic the function that certain mobile devices expect.

As the current through sense resistor R12 increases, the voltage across it increases. This voltage is sensed and amplified by U2 and Q1 and the resistors R9, R10, and R13. A voltage proportional to the output current is generated across R8. When this voltage is large enough, diode D6 conducts and injects current into the summing junction of the LM2734. The summing junction is used to regulate the output voltage, and so this additional current causes the output voltage to decrease in proportion to the output current.

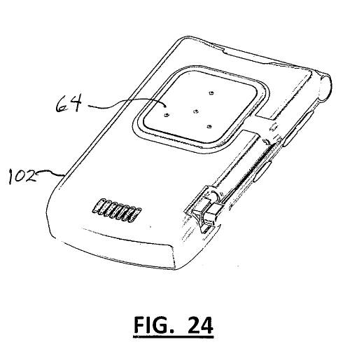

Constellation Module Overview: The Constellation Module 64 facilitates rapid enablement of a broad range of small devices. FIG. 24 shows an example implementation. Here the constellation module 64 is embedded in a “shell”-type housing 102 for a mobile phone.

The Constellation Module allows technology implementers to design-in charging system pad compatibility with a minimum of effort. The Constellation Module makes a “black box” out of the wireless charging system technology, simplifying the interface to just two wires—power and ground. For example, the outer dimensions of a useful Constellation Module measure 1.350″×1.350″×0.115″. Example output ratings are as follows:
Output Voltage 5.0V (0.8V-9.0V factory adjustable)
Output Current 550 mA (100 mA-1.2A factory adjustable)

Refer to Table 1 for Constellation Module Pinouts. Refer to FIG. 4 for pinout orientation.

TABLE 4

| | |
|---|---|
| 1 | V+ |
| 2 | NC |
| 3 | NC |
| 4 | NC |
| 5 | GND |

The Constellation Module™ allows charging system wireless power technology to be implemented in a variety of applications. The Constellation Module makes a “black box” out of the wireless power technology, simplifying the interface to just two wires—power and ground.

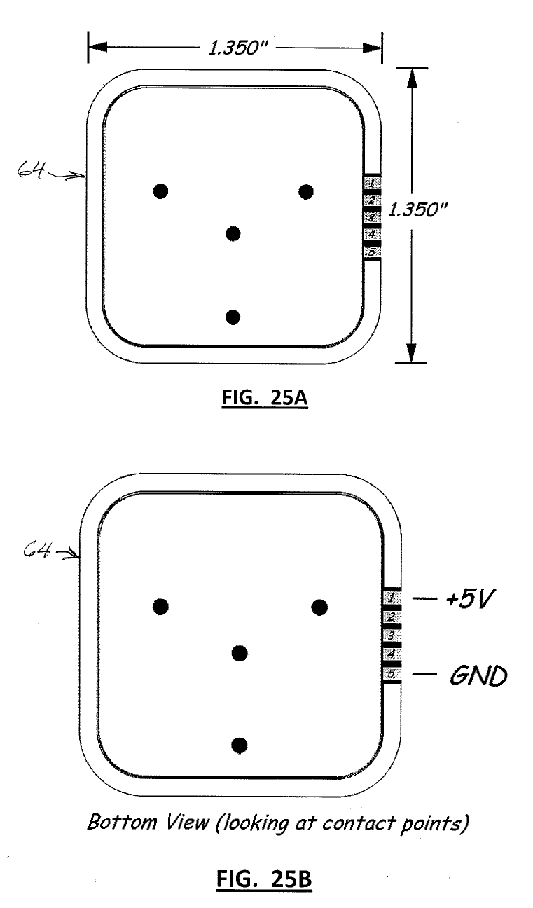

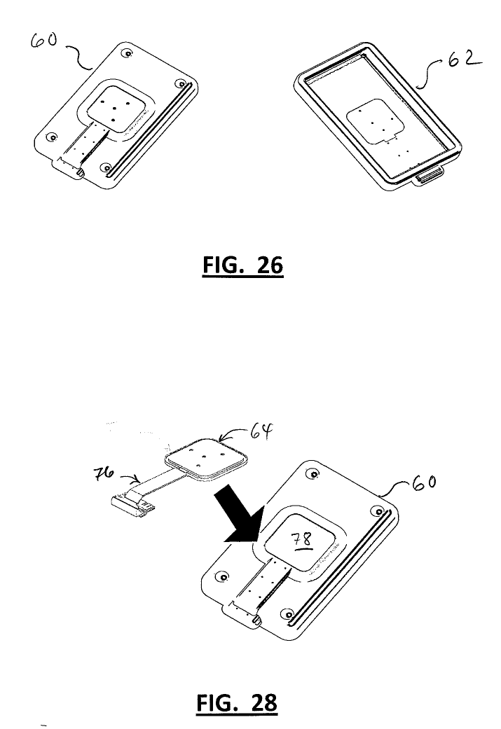

In an alternate embodiment of the invention, the example constellation module 64 shown in FIGS. 25A-B can be embedded in a “gel” type skin to easily “enable” common wireless devices to be charged by the charging pad of this invention. FIG. 26 shows the two halves of a gel-type case, consisting of an upper section 60 and a lower section 62.

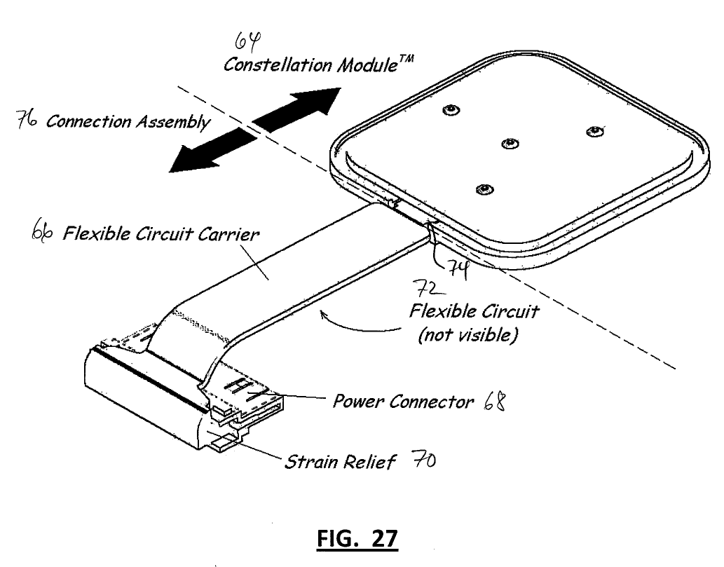

The design implementation can be broken into two tasks: 1) the design of an attractive, ergonomic “gel” skin, and 2) the design of the connection assembly—the connection between the constellation module 64 and the device 20. The focus of this application note will be the task of designing the connection assembly 76. FIG. 27 shows the wireless power assembly comprising the constellation module 64, flexible circuit carrier 66, flexible circuit 72 (not visible), strain relief 70, and power connector 68. Note that the exact implementation of the connection assembly will vary depending on the specific device being enabled. Nevertheless, FIG. 27 helps to illustrate the functions needed in such enablements.

The solution includes two main components, the gel case, and the wireless power Assembly, which is insert-molded into the gel case.

Here, insert molding involves the rigid constellation module 64 and semi-rigid connection assembly 76 and requires proper gating to ensure the material does not flow into unwanted areas. In particular the gel material should not flow into the connector cavity 78 thereby interfering with the electrical connection to the device. The gates should also prevent material entering the cavity 78 from pulling up the flexible circuit board from the carrier or strain relief 70. The material should also be blocked from the top and bottom surface of the constellation module 64. Any material on either the top or bottom of the constellation module will interfere with operation and increase the overall thickness of the design.

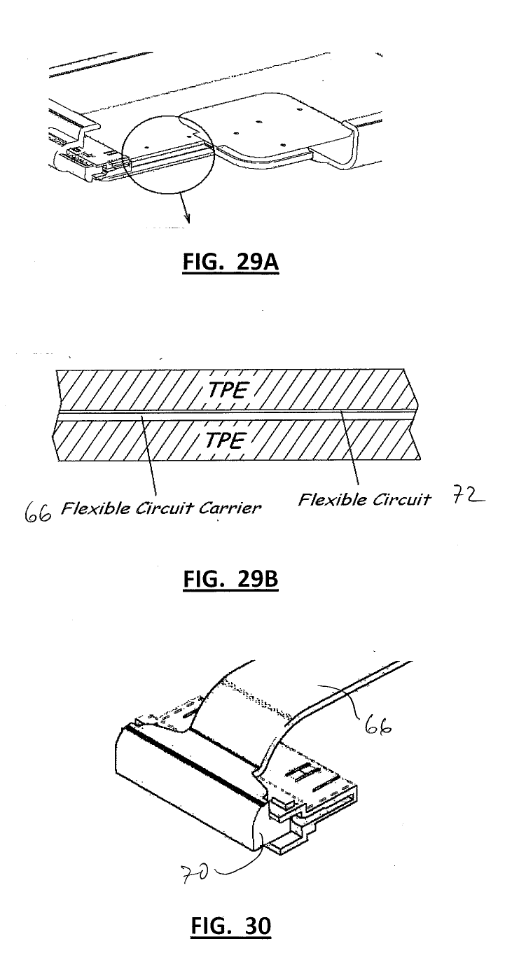

The constellation module 64 and the thermoplastic elastomer (TPE) material will chemically bond thereby creating a durable and reliable joint. The electrical connection between the constellation module 64 and the power connector 68 is established through traces on a flexible printed circuit 72, also called a flat flexible circuit (FFC). As shown in FIG. 29B, the flexible circuit 72 is laminated to a carrier 66 to provide stability and durability. The laminate is insert-molded within the TPE or other “gel” material.

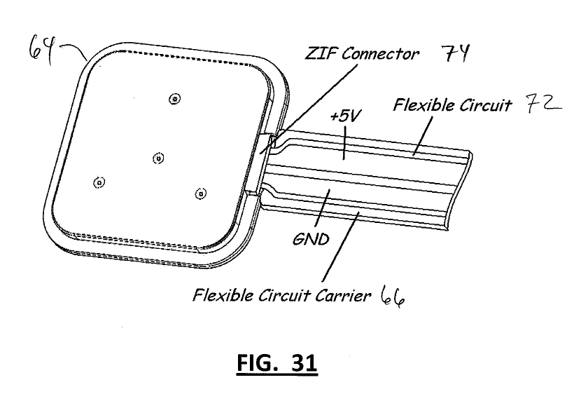

Some type of strain relief mechanism is required to ensure the reliability of the connection between the flexible circuit carrier 66 and the power connector 68. FIG. 30 shows an example where the flexible circuit carrier 66 and strain relief 70 are a single unit molded of plastic. In this case, the strain relief 70 also serves as a gate to prevent material from flowing into the connector 68 during the overmolding process.

The strain relief 70 relieves the load on the connector 68 from the flexible circuit 72. The flexible circuit 72 does not have the ability to mechanically retain or stabilize the connector 68. Any forces acting between the connector 68 and the flexible circuit 72 could result in damage to the electrical connections critical for operation.

As shown in FIG. 31, the connection assembly 76 interfaces to the constellation module 64 by plugging into a ZIF connector 74 on the constellation module 64. The flexible circuit carrier 66 should come flush to the constellation module housing. The flexible circuit 72 should extend further and into the ZIF connector 74. The power connector 68 for the target device 20 should protrude as little as possible. Ideally the connector 68 would not protrude from the device it is plugged into further than the thickness of the gel case itself. However, this is not always possible. This requirement may call for a custom connector to be manufactured.

The foregoing description is considered as illustrative of the principles of the invention. Furthermore, since numerous modifications and changes will readily occur to those skilled in the art, it is not desired to limit the invention to the exact construction and process shown and described above. Accordingly, resort may be made to all suitable modifications and equivalents that fall within the scope of the invention. The words “comprise,” “comprises,” “comprising,” “include,” “including,” and “includes” when used in this specification are intended to specify the presence of stated features, integers, components, or steps, but they do not preclude the presence or addition of one or more other features, integers, components, steps, or groups thereof.

The embodiments of the invention in which an exclusive property or privilege is claimed are defined as follows:

1. A wireless power delivery system comprising a set of flat electrodes constituting a surface, said electrodes powered by a control unit and when operating, generating a predetermined voltage potential.

2. The wireless power delivery system of claim 1 wherein receiver devices rest upon the surface to receive wireless power.

3. Receiver devices of claim 2 wherein each receiver device contains electronics to convert the standard output of the power delivery system to accommodate the requirements of the target device the receiver device is powering.

4. The wireless power delivery system of claim 1 wherein a system controller monitors and delivers power to said surface electrodes, said system controller having several modalities of operation to provide functionality to said wireless power delivery system.

5. The system controller of claim 4 wherein a spark suppression circuit prevents a spark if a short is suddenly presented across the pad during operation.

6. The spark suppression circuit of claim 5 employing low output capacitance.

7. The spark suppression circuit of claim 5 employing current limiting.

8. The spark suppression circuit of claim 5 employing rapid shutdown.

9. The wireless power delivery system of claim 1 wherein the design is sought to provide universal compatibility among a wide range of target devices.

10. The wireless power delivery system of claim 9 wherein a standard geometry is employed to provide for universal compatibility.

11. The wireless power delivery system of claim 1 wherein a power management scheme is implemented.

12. The power management scheme of claim 11 wherein voltage discrimination is used.

13. The power management scheme of claim 11 wherein digital power management communication is used.

14. The voltage discrimination scheme of claim 12 wherein predetermined voltage ranges are defined to indicate predetermined power output capabilities, said capabilities thereby detectable by target devices by the measurement of said predetermined voltage present on said wireless power delivery surface.

15. The receiver device of claim 2 wherein the electrical contact to the surface is provided by contact balls.

16. The receiver device of claim 15 wherein the contact balls make electrical connection with the receiver device electronics through a coil spring with a conical taper.

17. The receiver device of claim 15 wherein the conical taper coil springs make electrical contact with pads on the printed circuit forming the receiver device.

18. The receiver of claim 2 wherein magnets are used to increase the force exerted by the contact points to the surface electrodes of the power delivery surface.

19. The receiver of claim 2 wherein a diode rectifier is used to rectify the output from the plurality of contact points.

20. The diode rectifier of claim 19 wherein a resister and capacitor are used to present the required detectable response characteristics to the system controller such that the system controller can detect its presence yet distinguish it from all other impedances.

21. The rectifier of claim 19 wherein an auxiliary rectifier provides the necessary impedance response for the system controller to detect.

22. The receiver of claim 2 wherein the power conditioning electronics provides a turn-on delay.

23. An active rectifier comprising a MOSFET and a controller.

24. The controller of claim 23 comprising an amplifier with an asymmetric element.

25. The controller of claim 24 providing a gate drive to the MOSFET such that the MOSFET mimics the operation of an active diode.

26. A squelching power supply.

27. The squelching power supply of claim 26 wherein the output drives the controller of an active diode.

28. A system of active diodes and a squelching power supply forming an active bridge rectifier, said rectifier having the characteristic that at low input voltages rectification is performed by the intrinsic diodes of the MOSFET's and that at high voltages rectification is performed by the active diodes.

29. A module comprising a set of contacts compatible with the geometry of surface electrodes on a power delivery surface, a rectifier, and a power conditioning unit.

30. The module of claim 29 packaged in a housing that can be insert molded into a variety of materials.

31. The module of claim 29 comprising a circuit for power conditioning.

32. The circuit for power conditioning of claim 31 wherein an impedance recognizable by a system controller is included.

33. The circuit for power conditioning of claim 31 wherein a startup delay circuit is included.

34. The circuit for power conditioning of claim 31 wherein a current limiter is included.

35. The current limiter of claim 24 wherein a differential amplifier, a sensing resistor and a diode feed a current sense signal back into the summing junction of a regulator device.

36. The module of claim 29 wherein a ZIF socket is used to connect the power output to a flat, flexible conductor.

37. A mass producible power delivery surface.

38. The power delivery surface of claim 37 wherein a plastic base accepts stamped metal electrode strips.

39. The power delivery surface of claim 38 wherein leaf springs are used to connect the metal electrode strips to a printed circuit board.

40. The power delivery surface of claim 39 wherein a printed circuit board seats in a predefined orientation on the plastic base.

41. The power delivery surface of claim 40 wherein a cover encloses said printed circuit board, printed circuit board then making contact with said leaf springs.
